(19) United States
(12) Patent Application Publication
(10) Pub. No.: US 2004/0072448 A1
(43) Pub. Date: Apr. 15, 2004

(54) Protecting delicate semiconductor features during wet etching

(76) Inventors: Justin K. Brask, Portland, OR (US); Vijayakumar S. Ramachandrarao, Hillsboro, OR (US); Kevin P. O'Brien, Portland, OR (US); Patrick M. Paluda, Aloha, OR (US)

Correspondence Address: Timothy N. Trop, TROP, PRUNER & HU, P.C., STE 100, 8554 KATY FWY, HOUSTON, TX, 77024-1841, US

(21) Appl. No.: 10/271,446

(22) Filed: Oct. 15, 2002

(51) Int. Cl. H01L 21/302; H01L 21/461

(52) U.S. Cl. 438/745

(57) ABSTRACT

A wet etching solution may be utilized to remove insulator material between delicate structures. Surface tension effects of the wet etching solution may tend to collapse or deform delicate features. By applying sonic energy during the wet etch process and/or the removal of the wafer from a wet etching bath, the adverse effects of surface tension may be counteracted.

### BACKGROUND

This invention relates generally to the fabrication of integrated circuit components.

In a variety of integrated circuit operations, etching may be utilized to remove insulator materials from other materials such as metal or conductive lines. As dimensions scale, the resulting features, such as metal lines, become extremely delicate, especially once removed from their insulative support material such as a dielectric material.

In many cases, it is desirable to form metal lines that are free of any intervening dielectric material utilized in the process of forming the metal lines. For example, in connection with copper interconnect lines, it may be desirable to reduce the dielectric constant between copper interconnect lines. One way to do this is to remove the dielectric, thereby decreasing the dielectric constant and reducing the capacitance between adjacent lines.

However, as features become extremely small, wet etching to remove the intervening insulator or dielectric material has become problematic. In the course of removing a wafer from a wet bath, the features, freed of their supportive insulating materials, may tend to collapse or to pull against one another.

One way to avoid this problem is to use plasma or dry etching. However, plasma etching may not be desirable in a variety of situations because of the inability of particular plasma etchants to etch particular dielectric materials.

Thus, there is a need to provide ways to use wet etching for removing insulating materials between relatively delicate features.

### BRIEF DESCRIPTION OF THE DRAWINGS

FIG. 1 is a greatly enlarged partial top plan view of a semiconductor wafer in accordance with one embodiment of the present invention;

FIG. 2 is a greatly enlarged cross-sectional view taken generally along the line 2-2 in FIG. 1 in accordance with one embodiment of the present invention;

FIG. 3 is a schematic depiction of a wafer in a wet etch bath in accordance with one embodiment of the present invention; and

FIG. 4 is a process flow in accordance with one embodiment of the present invention.

### DETAILED DESCRIPTION

In a variety of cases, features may be defined in an insulator. Subsequently, it may be desirable to remove the insulator, freeing the features. Examples of such features may be metal lines. Examples of metal lines include copper interconnects formed using the damascence process. Other examples include microelectromechanical structures, such as switches and filter elements.

In many cases the features that are formed are extremely small-sized and are, therefore, relatively delicate. These features may be formed in an insulator or dielectric. In order to free the features, the dielectric may be removed using wet etching. However, the inventors of the present invention have determined that, in the course of removing the wafers containing the features from a wet etching bath, surface tension forces cause the features to be pulled into one another or to collapse. In other words, as the wafer is removed from the bath, the forces of surface tension draw features together causing the destruction of those features.

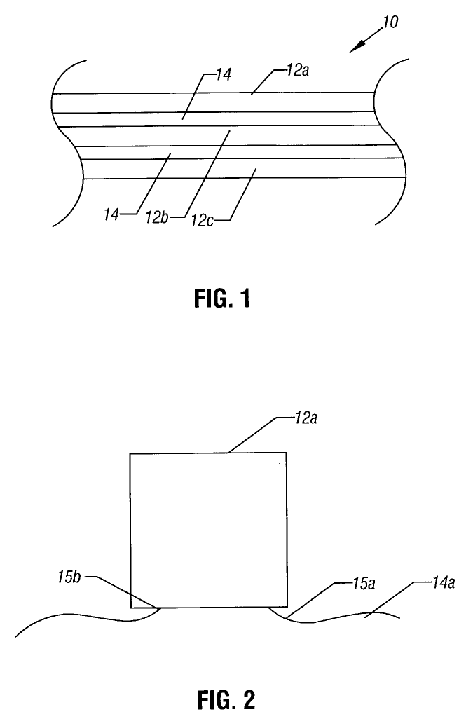

Thus, referring to FIG. 1, a plurality of lines 12a, 12b, and 12c, which may be metal or copper lines, may be arranged in close proximity to one another. The lines 12 may be separated by intervening interlayer dielectric material 14. In some cases the lines 12 may be supported by vias or pegs. As an example, the lines 12 may be on the order of ten nanometers wide. It may be desirable to remove the dielectric material 14 in order to use an air spacing between the lines 12. The use of air spacing may reduce the dielectric constant. However, because the dielectric 14 tends to support the lines 12, the removal of the dielectric 14 may leave the lines 12 in a vulnerable situation.

In the course of removing the dielectric material from around the metal lines, there comes a point when the dielectric material 14a is progressively removed from beneath the metal line 12a as shown in FIG. 2. Eventually, the metal line 12a is completely free of attachment to the dielectric material.

As the dielectric material 14a is progressively etched away, the metal line 12a may be distorted through the action of surface tension beneath the metal line 12a in the regions 15. In particular, the forces of surface tension may tend to distort the line 12a twisting it in one direction or the other.

The etching progresses along the regions 15a and 15b under the line 12a. Generally, one of the regions 15a or 15b progresses more quickly than the other. As a result of this, a differential force is applied to the metal line 12a as a result of surface tension. This may cause distortion and, ultimately, destruction of the metal line 12a.

However, with the application of sonication during etching, the surface tension forces are broken up and the adverse effects of surface tension may be removed. The metal line 12a may be completely freed of the surrounding dielectric 14a without being distorted.

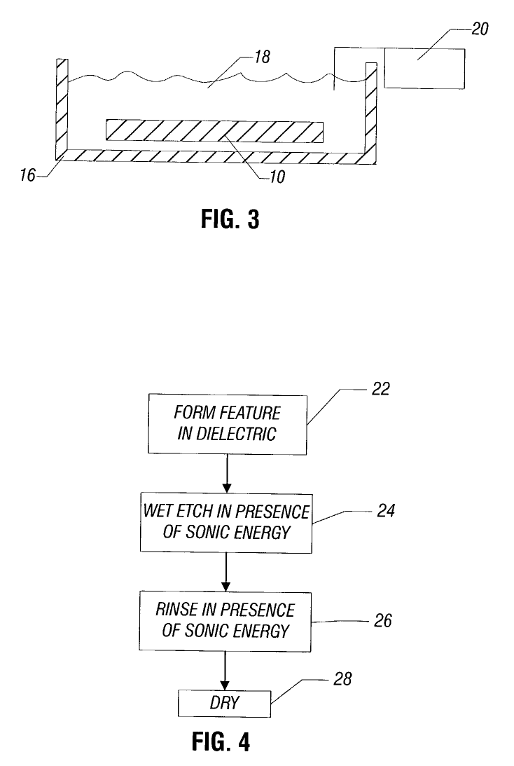

Thus, referring to FIG. 3, a wafer 10 may be placed in a wet etch bath 18 in a wet etch immersion tank 16. A sonic energy source 20, such as an ultra or megasonic energy source, may be utilized to sonicate the wet etch bath 18.

When the wafer 10 is being removed from the bath 18, the forces of surface tension may be broken up, relieving the force of surface tension and reducing the tendency of the features formed on the wafer 10, such as the lines 12, to collapse into one another.

Referring to FIG. 4, in accordance with some embodiments of the present invention, a feature such as a metal line may be formed in a dielectric material as indicated in block 22. Thereafter, the wafer with the feature thereon may be wet etched in the presence of sonic energy to remove the intervening dielectric as indicated in block 24. Because of the application of sonic energy, surface tension forces may be broken up, enabling the metal line to be etched free of the dielectric and also enabling the wafer 10 to be removed from the bath 18 without destructive effects.

Subsequently, it may be desirable to rinse the wafer 10 as indicated at 26, for example, in de-ionized water. Again, sonic energy may be applied to break up surface tension forces and to prevent the destructive attractive forces that may result from surface tension caused by the rinse liquid. Subsequently, the wafer may be dried as indicated in block 28.

In some embodiments ultrasonic energy in the frequency range between approximately 10 kilohertz and 100 kilohertz may be applied. In some embodiments, megasonic energy in the range of approximately 500 to 1000 kilohertz may be applied. The sonic energy may be applied by transducers that are located in, or near an immersion tank with the wafer immersed in the tank.

In some cases, the sonic energy may be applied to a film of etching solution. For example, in some cases, etching solution may be sprayed onto the wafer being etched. A film or layer of the etching solution may collect on the surface of the wafer. Sonic energy may be applied directly to this film or layer even when the entire wafer is not immersed.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
exposing a wafer to a wet etching solution; and
while the wafer is exposed to said wet etching solution, applying sonic energy to said solution.

2. The method of claim 1 including applying megasonic energy to the solution.

3. The method of claim 1 including applying ultrasonic energy to the solution.

4. The method of claim 1 including etching a dielectric material.

5. The method of claim 4 including forming air gaps between metal lines by etching a dielectric material between the metal lines.

6. The method of claim 1 including removing the wet etching solution from the wafer using a rinse.

7. The method of claim 6 including applying sonic energy while the wafer is at least partially exposed to said rinse.

8. The method of claim 1 including forming an air gap between copper lines by wet etching a dielectric between the metal lines.

9. The method of claim 1 including forming a metal line surrounded by a dielectric and etching the dielectric from under the metal line while applying sonic energy.

10. A method comprising:
while a wafer is at least partially immersed in a wet etching solution, applying sonic energy to said solution.

11. The method of claim 10 including applying megasonic energy to said solution.

12. The method of claim 10 including applying ultrasonic energy to said solution.

13. The method of claim 10 including using said wet etching bath to etch a dielectric material.

14. The method of claim 13 including using said etching bath to etch a dielectric material from between metal lines.

15. The method of claim 10 including rinsing said wafer after removing said wafer from the wet etching bath and applying sonic energy to said rinse.

16. The method of claim 10 including immersing a wafer in a wet etching solution and applying sonic energy to said solution while said wafer is immersed in said solution.

17. A method comprising:
forming a structure including a metal line separated by interlayer dielectric;
etching said interlayer dielectric in a wet etching solution; and
applying sonic energy to said solution.

18. The method of claim 17 including applying megasonic energy to said solution.

19. The method of claim 17 including applying ultrasonic energy to said solution.

20. The method of claim 17 including forming said metal lines in dielectric using a damascene process.

21. The method of claim 17 including rinsing said metal line after etching said interlayer dielectric.

22. The method of claim 21 including applying sonic energy to a rinse used to rinse said metal line.

23. The method of claim 17 including immersing a wafer having said metal lines in a wet etching solution and applying sonic energy to said solution.

24. The method of claim 16 including etching away the interlayer dielectric from beneath a metal line while applying sonic energy.
